(19) United States
(12) Patent Application Publication
(10) Pub. No.: US 2026/0243848 A1
(43) Pub. Date: Aug. 20, 2026

(54) DEGRADATION DETERMINATION DEVICE AND DEGRADATION DETERMINATION METHOD

(71) Applicant: Mitsubishi Electric Corporation, Chiyoda-ku, Tokyo (JP)

(72) Inventor: Shohei NISHIMURA, Chiyoda-ku, Tokyo (JP)

(73) Assignee: Mitsubishi Electric Corporation, Chiyoda-ku, Tokyo (JP)

(21) Appl. No.: 19/164,579

(22) PCT Filed: Jun. 6, 2023
(86) PCT No.: PCT/JP2023/021051

§ 371 Date: Sep. 11, 2025

(51) Int. Cl. G01R 31/42

(52) U.S. Cl. CPC G01R 31/42

(57) ABSTRACT

A degradation determination device determines presence or absence of degradation in a constant-voltage power supply that outputs, to electronic equipment including a switching element, an operating voltage for the switching operation of the switching element. The degradation determination device includes a signal processor and a degradation determiner. The signal processor generates, from an output voltage of the constant-voltage power supply, voltage data based on an amplitude of the output voltage. The degradation determiner acquires a startup time of the constant-voltage power supply from the voltage data and a startup command directed to the electronic equipment, and determines presence or absence of degradation in the constant-voltage power supply from the startup time.

### TECHNICAL FIELD

The present disclosure relates to a degradation determination device and a degradation determination method.

### BACKGROUND ART

Railway vehicles are each equipped with electronic equipment and a constant-voltage power supply that outputs, to the electronic equipment, an operating voltage for switching operation of a switching element included in the electronic equipment. Patent Literature 1 discloses an example of a degradation determination device that determines presence or absence of degradation in a constant-voltage power supply for stable operation of electronic equipment. The degradation detection device disclosed in Patent Literature 1 detects, based on a timing of rising of an input voltage of a low-voltage power supply as a detection target, a timing at which a charge voltage of a smoothing capacitor included in the low-voltage power supply has increased to reach a predetermined voltage, and a timing of rising of an output voltage of the low-voltage power supply, degradation of the low-voltage power supply.

### CITATION LIST

### Patent Literature

Patent Literature 1: Unexamined Japanese Patent Application Publication No. 2016-201934

### SUMMARY OF INVENTION

### Technical Problem

The degradation detection device disclosed in Patent Literature 1 needs to detect and analyze a voltage of the smoothing capacitor installed in the low-voltage power supply as the detection target in addition to input and output of the low-voltage power supply as the detection target, making a method for determination on degradation complicated and the structure of the degradation detection device complex.

The present disclosure is made in view of the above circumstances, and an objective of the present disclosure is to provide a degradation determination device and a degradation determination method for determining presence or absence of degradation in a constant-voltage power supply with simple configuration.

### Solution to Problem

To achieve the aforementioned objective, a degradation determination device according to the present disclosure is a degradation determination device for determining presence or absence of degradation in a constant-voltage power supply that outputs, to electronic equipment including a switching element, an operating voltage for switching operation of the switching element, and includes a signal processor and a degradation determiner. The signal processor generates, from an output voltage of the constant-voltage power supply, voltage data based on an amplitude of the output voltage. The degradation determiner acquires a startup time of the constant-voltage power supply from the voltage data and a startup command directed to the electronic equipment, and determines presence or absence of degradation in the constant-voltage power supply from the startup time.

### Advantageous Effects of Invention

A degradation determination device according to the present disclosure acquires a startup time of a constant-voltage power supply from a startup command directed to electronic equipment and voltage data indicating an amplitude of an output voltage of the constant-voltage power supply, and determines presence or absence of degradation in the constant-voltage power supply from the startup time. Since the degradation determination device does not need to acquire electrical physical quantities of the internal elements of the electronic equipment, a degradation determination device can be achieved that determines presence or absence of degradation in a constant-voltage power supply with simple configuration.

### BRIEF DESCRIPTION OF DRAWINGS

FIG. 1 is a block diagram of a degradation determination device according to Embodiment 1;

FIG. 2 illustrates hardware configuration of the degradation determination device according to Embodiment 1;

FIG. 3 is a flowchart illustrating example operation of degradation determination processing executed by the degradation determination device according to Embodiment 1;

FIG. 4 illustrates an example relationship among a startup command, an output voltage, and a startup time of a constant-voltage power supply that is a degradation determination target of the degradation determination device according to Embodiment 1;

FIG. 5 is a block diagram of a degradation determination device according to Embodiment 2;

FIG. 6 is a block diagram of a degradation determination device according to Embodiment 3;

FIG. 7 is a block diagram of a modified example of the degradation determination device according to the embodiments; and

FIG. 8 illustrates a modified example of the hardware configuration of the degradation determination device according to the embodiments.

### DESCRIPTION OF EMBODIMENTS

A degradation determination device and a degradation determination method according to embodiments of the present disclosure are described in detail below with reference to the accompanying drawings. In the drawings, the elements identical or corresponding to each other are assigned the same reference sign.

### Embodiment 1

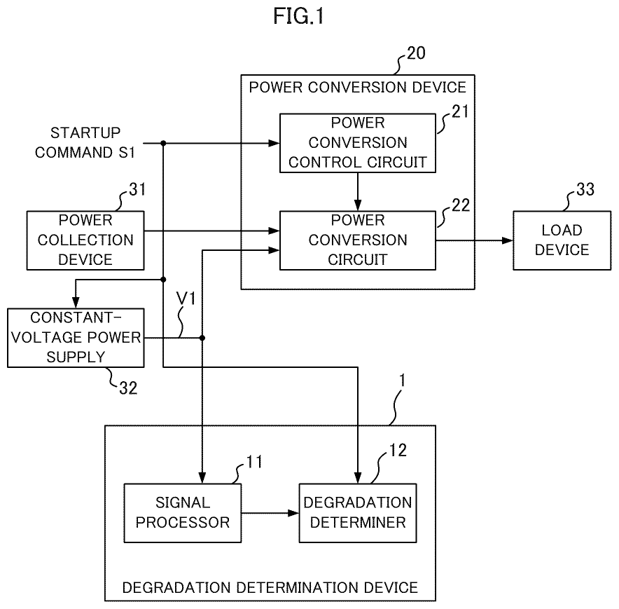

Examples of electronic equipment that includes a switching element include a power conversion device mounted in a railway vehicle. A degradation determination device according to Embodiment 1 is described below using, as an example, a degradation determination device that determines presence or absence of degradation in a constant-voltage power supply that outputs to a power conversion device an operating voltage for switching operation of switching elements. A degradation determination device 1 according to Embodiment 1 that is illustrated in FIG. 1 determines presence or absence of degradation in a constant-voltage power supply 32 that outputs an operating voltage to a power conversion device 20.

The power conversion device 20 starts operation in accordance with a startup command S1, converts power supplied from a power collection device 31 into power to be supplied to a load device 33 and supplies the resultant power to the load device 33. The power conversion device 20 includes a power conversion control circuit 21 that generates multiple gate signals that are each for controlling the corresponding switching element of multiple switching elements and a power conversion circuit 22 that includes the multiple switching elements and converts the power supplied from the power collection device 31 into power to be supplied to the load device 33.

In accordance with the startup command S1 supplied from a driver cab, the power conversion control circuit 21 starts operation and generates the gate signals. The startup command S1 is a signal for providing an instruction for startup of the power conversion device 20. The startup of the power conversion device 20 is taken to include restart. The startup command S1 is, for example, a signal that reaches a high (H) level after elapse of a certain time after operation of a switch for providing an instruction of start of operation of the railway vehicle and that reaches a low (L) level at an end of running of the railway vehicle. The switch for providing an instruction of start of operation of the railway vehicle is, for example, an activation switch that is installed in the driver cab to raise the pantograph, a type of the power collection device 31, to thereby bring the pantograph into contact with an overhead wire, a type of a power supply line.

Each of the switching elements included in the power conversion circuit 22 is under on-off control with the gate signal output by the power conversion control circuit 21 and performs the switching operation. The operating voltage output by the constant-voltage power supply 32 allows each of the switching elements of the power conversion circuit 22 to perform the switching operation. Through the switching operation of each of the switching elements, the power conversion circuit 22 converts the power supplied from the power collection device 31 into power to be supplied to the load device 33 and supplies the resultant power to the load device 33.

The power conversion circuit 22 includes, for example, an inverter circuit that converts direct-current power supplied from the power collection device 31 into alternating-current power and supplies the alternating-current power to the load device 33.

The power collection device 31 is, for example, a pantograph, a contact shoe, or the like, and acquires power supplied from a substation via a power supply line. The power collection device 31 supplies the acquired power to the power conversion circuit 22 included in the power conversion device 20.

The load device 33 is electronic equipment that consumes electric power, such as lightning equipment, an air conditioner, or an electric motor that is mounted in the railway vehicle.

The constant-voltage power supply 32 starts operation upon startup of the power conversion device 20. In detail, the constant-voltage power supply 32 starts operation upon the startup command S1 directed to the power conversion device 20 reaching the H level, and outputs, to the power conversion circuit 22 included in the power conversion device 20, the operating voltage that is an alternating-current voltage for the switching operation of the switching elements.

The degradation determination device 1 determines presence or absence of degradation in the aforementioned constant-voltage power supply 32. The degradation determination device 1 includes a signal processor 11 that generates, from an output voltage V1 of the constant-voltage power supply 32, voltage data based on an amplitude of the output voltage V1, and a degradation determiner 12 that acquires a startup time of the constant-voltage power supply 32 from the startup command S1 and the voltage data and determines presence or absence of degradation in the constant-voltage power supply 32 from the startup time.

The signal processor 11 performs signal processing of the output voltage V1 of the constant-voltage power supply and thereby generates the voltage data based on the amplitude of the output voltage. In Embodiment 1, the signal processor 11 performs, based on a low pass filter (LPF), filtering of waveform data indicating the output voltage V1 of the constant-voltage power supply and thereby generates envelope data in an analog domain indicating an envelope of the waveform data. The signal processor 11 performs analog-to-digital (A/D) conversion of the envelope data in the analog domain and thereby generates voltage data in the digital domain. The signal processor 11 transmits the generated voltage data to the degradation determiner 12.

The degradation determiner 12 acquires the startup command S1 directed to the power conversion device 20 and acquires the voltage data from the signal processor 11. The degradation determiner 12 acquires the startup time of the constant-voltage power supply 32 from the startup command S1 directed to the power conversion device 20 and the voltage data. In detail, the degradation determiner 12 acquires, as the startup time, an elapsed time from when the startup command S1 instructs startup of the power conversion device 20 until the amplitude indicated by the voltage data reaches a threshold. The threshold is set based on an operating rated voltage necessary for the power conversion device 20 to perform the switching operation of the multiple switching elements.

The degradation determiner 12 determines presence or absence of degradation in the constant-voltage power supply 32 from the startup time of the constant-voltage power supply 32. The degradation determiner 12 outputs a result of the determination to a non-illustrated output device, a non-illustrated external equipment, or the like. As a result, for example, causing an output device including a display screen to display the result of the determination on the screen enables prompting a maintenance work on the constant-voltage power supply 32.

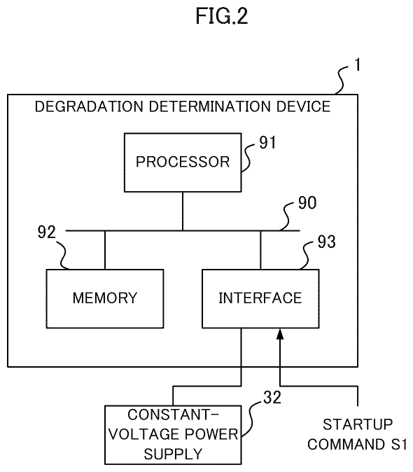

FIG. 2 illustrates hardware configuration of the degradation determination device 1 having the aforementioned configuration. The degradation determination device 1 includes a processor 91, a memory 92, and an interface 93. The processor 91, the memory 92, and the interface 93 are connected to one another with a bus 90. The functions of each element of the degradation determination device 1 are achieved by software, firmware, or a combination of software and firmware. The software and the firmware are described as a program and are stored in the memory 92. The processor 91 reads and executes the program stored in the memory 92 to achieve the functions of the above elements. In other words, the memory 92 stores a program for executing the processing of the degradation determination device 1.

The memory 92 is, for example, a nonvolatile or volatile semiconductor memory such as a random-access memory (RAM), a read-only memory (ROM), a flash memory, an erasable programmable ROM (EPROM), or an electrically erasable programmable ROM (EEPROM), or a magnetic disk, a flexible disk, an optical disc, a compact disc, a minidisc, or a digital versatile disc (DVD).

The degradation determination device 1 is connected to the constant-voltage power supply 32 and acquires the startup command S1 via the interface 93. The interface 93 includes an interface module complying with one or more standards as appropriate for connection targets.

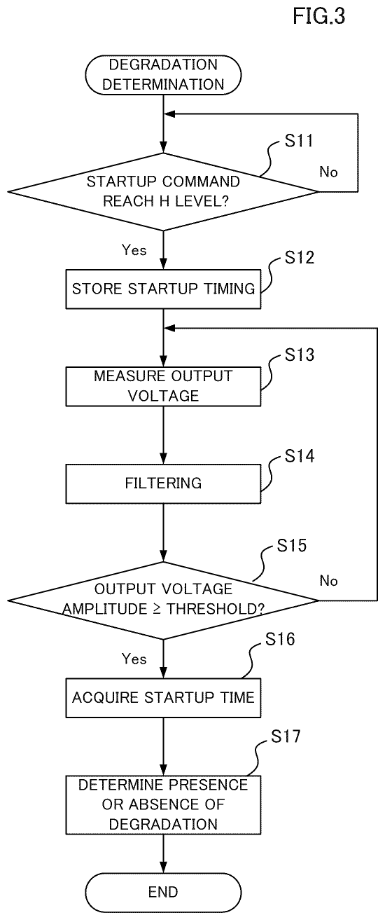

The degradation determination device 1 having the aforementioned configuration starts processing as illustrated in FIG. 3 for determining presence or absence of degradation at the start of the operation of the railway vehicle, specifically, upon the activation switch is operated for raising the pantograph, a type of the power collection device 31, to thereby bring the pantograph into contact with an overhead wire, a type of a power supply line.

The degradation determiner 12 determines whether the startup command reaches the H level (step S11). While the startup command is at the L level (No in step S11), the degradation determiner 12 repeats the processing of step S11.

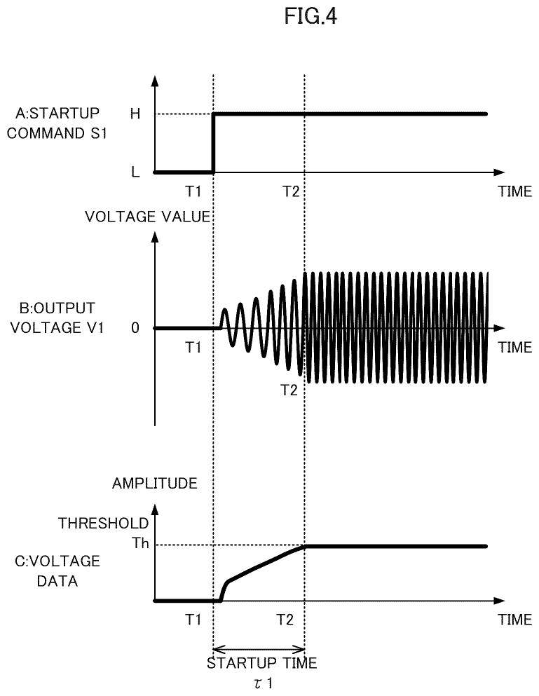

When the startup command reaches the H level, (Yes in step S11), the degradation determiner 12 stores a timing at which the startup command reaches the H level (step S12). When the startup command S1 reaches the H level at a time Tl as illustrated in the graph A of FIG. 4, the degradation determiner 12 stores the time T1.

As illustrated in the graph B of FIG. 4, when the startup command S1 reaches the H level, the constant-voltage power supply 32 starts outputting the operating voltage to the power conversion circuit 22. The amplitude of the alternating-current voltage output by the constant-voltage power supply 32 gradually increases.

As illustrated in FIG. 3, after the startup command reaches the H level, the signal processor 11 measures the output voltage V1 of the constant-voltage power supply 32 (step S13). The signal processor 11 performs LPF-based filtering of waveform data in an analog domain indicating the output voltage V1 of the constant-voltage power supply 32 (step S14). By performance of the LPF-based filtering and digital conversion, as illustrated in the graph C of FIG. 4, voltage data is obtained that indicates the envelope of the waveform data of the output voltage of the constant-voltage power supply 32 that is illustrated in the graph B. The signal processor 11 transmits the voltage data to the degradation determiner 12.

As illustrated in FIG. 3, the degradation determiner 12 determines whether the amplitude of the output voltage V1 of the constant-voltage power supply 32 that is indicated by the voltage data reaches the threshold (step S15). While the amplitude of the output voltage V1 of the constant-voltage power supply 32 does not reach the threshold (No in step S15), the degradation determination device 1 repeats the aforementioned processing from step S13.

When the amplitude of the output voltage V1 of the constant-voltage power supply 32 reaches the threshold (Yes in step S15), the degradation determiner 12 acquires, as the startup time, an elapsed time from the startup timing stored in step S12 until the amplitude of the output voltage of the constant-voltage power supply 32 reaches the threshold (step S16).

At a time T2 at which the amplitude of the output voltage V1 of the constant-voltage power supply 32 that is indicated by the voltage data reaches a threshold Th as illustrated in the graph C of FIG. 4, the degradation determiner 12 acquires, as the startup time, a time length t1 from the time T1 to the time T2.

As illustrated in FIG. 3, the degradation determiner 12 determines presence or absence of degradation in the constant-voltage power supply 32 from the startup time acquired in step S16 (step S17). In detail, the degradation determiner 12 determines whether the startup time acquired in step S16 is longer or equal to a reference time. The reference time is determined based on the startup time of the constant-voltage power supply 32 without degradation that is measured, for example, immediately after the start of utilization of the railway vehicle, during a trial run before operation of the railway vehicle, or the like. Specifically, the reference time may be a value obtained by multiplying the startup time of the constant-voltage power supply 32 without degradation by a factor greater than 1, such as a factor greater than 1 and less than 1.5.

After completion of the processing in step S17, the degradation determination device 1 ends the degradation determination processing. The degradation determination device 1 executes the above-described processing when the startup command S1 changes from the L level to the H level, for example, at a time of starting operation of the railway vehicle, at a time of restarting the constant-voltage power supply 32 due to restart of the power conversion device 20, or the like.

As described above, the degradation determination device 1 according to Embodiment 1 acquires, as the startup time, a time length from a timing at which the startup command S1 changes from the L level to the H level until a timing at which the amplitude of the output voltage V1 of the constant-voltage power supply 32 reaches the threshold, and determines presence or absence of degradation in the constant-voltage power supply 32 based on the startup time. The degradation determination device 1 can acquire the startup time based on whether the voltage data, indicating the envelope of the waveform data that is obtained by performance of LPF-based filtering and digital conversion of the waveform data indicating the output voltage V1 of the constant-voltage power supply 32, reaches the threshold. The degradation determination device 1 does not need to perform measurement of electrical physical quantities of the internal elements of the constant-voltage power supply 32, analysis of waveform data, and other related processing. Due to this, the degradation determination device 1 have simple configuration.

As described above, the degradation determination device 1 does not need to acquire the electrical physical quantities of the internal elements of the constant-voltage power supply 32. This enables newly installing the degradation determination device 1 for determining presence or absence of degradation in an already-installed constant-voltage power supply into a railway vehicle without any change in the already-installed constant-voltage power supply.

### Embodiment 2

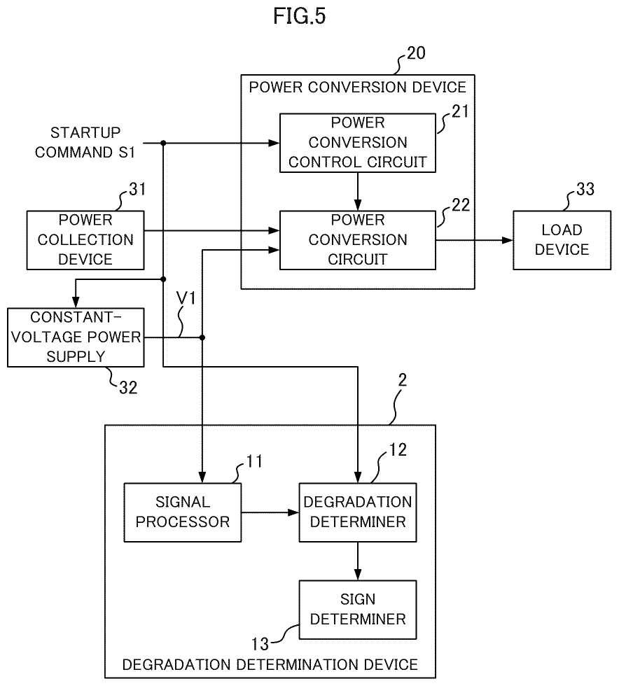

The degradation determination made by the degradation determination device 1 is not limited to the determination of presence or absence of degradation and may include a determination of presence or absence of a sign of degradation. A degradation determination device 2 according to Embodiment 2 that is illustrated in FIG. 5 includes a sign determiner 13 that determines presence or absence of a sign of degradation in the constant-voltage power supply 32, in addition to the elements included in the degradation determination device 1 according to Embodiment 1. The degradation determination device 2 has hardware configuration similar to that of the degradation determination device 1.

The degradation determiner 12 acquires the startup time of the constant-voltage power supply 32 each time the startup command S1 instructs startup of the power conversion device 20. Each time the degradation determiner 12 determines presence or absence of degradation of the constant-voltage power supply 32, the sign determiner 13 acquires the startup time of the constant-voltage power supply 32 and a result of the determination from the degradation determiner 12. The sign determiner 13 determines, based on a change over time in the startup time, presence or absence of a sign of degradation in the constant-voltage power supply 32. In Embodiment 2, the sign determiner 13 determines presence or absence of a sign of degradation in the constant-voltage power supply 32 based on a change over time in the startup time of the constant-voltage power supply 32 from when utilization of the railway vehicle is started. The sign determiner 13 is taken to pre-store information indicating a time point when utilization of the railway vehicle is started, for example, the date when the utilization of the railway vehicle is started, the date when the test run ends, and the like.

Each time the startup time is acquired from the degradation determiner 12, the sign determiner 13 acquires a moving average of the startup time of the constant-voltage power supply 32 and determines whether the moving average of the startup time is on an increase. In the case where the moving average of the startup time of the constant-voltage power supply 32 is on an increase, it can be deemed that a sign of degradation in the constant-voltage power supply 32 occurs. For example, the sign determiner 13 determines a first-order approximation equation from a time elapsed from the start of utilization of the railway vehicle and the moving average of the startup time of the constant-voltage power supply 32, and determines whether a slope of the determined first-order approximation equation is within a target range. The target range may be set based on a rate of increase in the startup time when degradation occurs in the constant-voltage power supply 32. For example, a value that is a half of the rate of increase in the startup time when degradation occurs in the constant-voltage power supply 32 may be set as an upper limit of the target range. The rate of increase in the startup time when degradation occurs in the constant-voltage power supply 32 may be obtained through an accelerated degradation test, simulation, or the like.

Similarly to the degradation determiner 12, the sign determiner 13 outputs a result of the determination to an output device, external equipment, or the like. As a result, for example, causing an output device including a display screen to display the result of the determination on the screen enables prompting a maintenance work on the constant-voltage power supply 32.

The degradation determination processing executed by the degradation determination device 2 is similar to the degradation determination processing executed by the degradation determination device 1 according to Embodiment 1 that is illustrated in FIG. 3. In step S17 illustrated in FIG. 3, the degradation determiner 12 determines presence or absence of degradation and the sign determiner 13 determines presence or absence of a sign of degradation.

As described above, with the degradation determination device 2 according to Embodiment 2, a determination on presence or absence of a sign of degradation in the constant-voltage power supply 32 can be made based on a change over time in the startup time of the constant-voltage power supply 32. Due to this configuration, for example, issuing a warning about a sign of degradation in the constant-voltage power supply 32 enables prompting a maintenance work of the constant-voltage power supply 32 before occurrence of degradation in the constant-voltage power supply 32.

### Embodiment 3

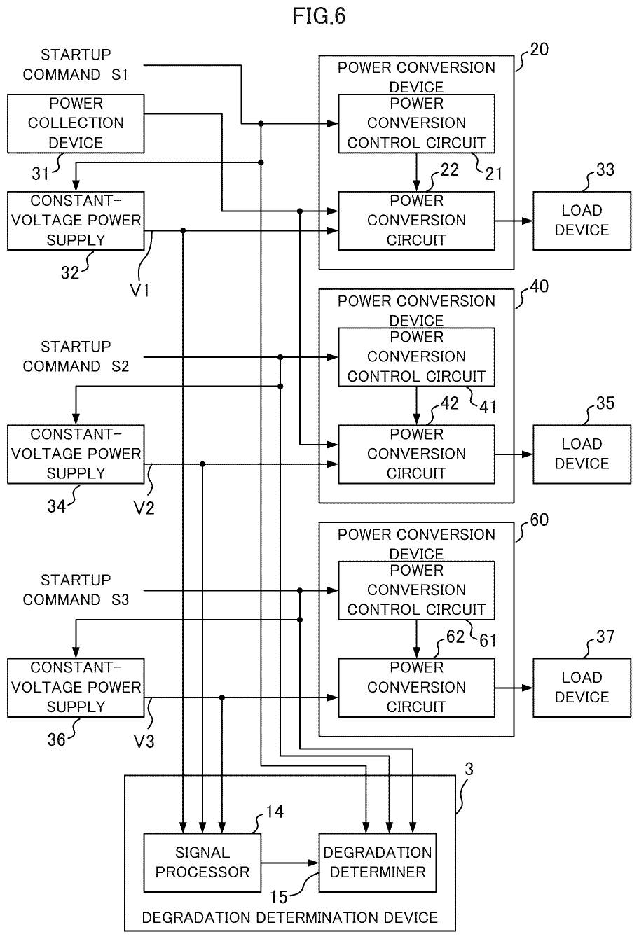

The degradation determination device may determine, from startup times of multiple constant-voltage power supplies, presence or absence of degradation in each constant-voltage power supply. A degradation determination device 3 illustrated in FIG. 6 determines presence or absence of degradation in multiple constant-voltage power supplies 32, 34 and 36 that each output, to the corresponding one of multiple power conversion devices 20, 40 and 60, the operating voltage for switching operation of switching elements.

The power conversion devices 20, 40 and 60 are electronic equipment installed in the same vehicle, more specifically, the same railway vehicle. Similarly to the power conversion device 20, the power conversion device 40 starts operation in accordance with a startup command S2, converts power supplied from the power collection device 31 into power to be supplied to a load device 35 and supplies the resultant power to the load device 35. The power conversion device 40 includes a power conversion control circuit 41 that generates gate signals for controlling switching elements and a power conversion circuit 42 that includes the multiple switching elements and converts the power supplied from the power collection device 31 into power to be supplied to the load device 35.

In accordance with the startup command S2 supplied from the driver cab, the power conversion control circuit 41 generates the gate signals. The startup command S2 is a signal for providing an instruction for startup of the power conversion device 40. The startup of the power conversion device 40 is taken to include restart.

The startup command S2 is, for example, a signal that reaches the H level after elapse of a certain time after operation of a switch for providing an instruction of start of operation of the railway vehicle and that reaches the L level at the end of the running of the railway vehicle.

Each of the multiple switching elements included in the power conversion circuit 42 is under on-off control with the corresponding gate signal output by the power conversion control circuit 41 and performs the switching operation. The operating voltage output by the constant-voltage power supply 34 allows each of the switching elements of the power conversion circuit 42 to perform the switching operation.

Through the switching operation of each of the switching elements, the power conversion circuit 42 converts the power supplied from the power collection device 31 into power to be supplied to the load device 35 and supplies the resultant power to the load device 35.

Similarly to the power conversion device 20, the power conversion device 60 starts operation in accordance with a startup command S3, converts power supplied from the power collection device 31 into power to be supplied to a load device 37 and supplies the resultant power to the load device 37. The power conversion device 60 includes a power conversion control circuit 61 that generates gate signals for controlling switching elements and a power conversion circuit 62 that includes the multiple switching elements and converts the power supplied from the power collection device 31 into power to be supplied to the load device 37.

In accordance with the startup command S3 supplied from the driver cab, the power conversion control circuit 61 generates the gate signals. The startup command S3 is a signal for providing an instruction for startup of the power conversion device 60. The startup of the power conversion device 60 is taken to include restart.

The startup command S3 is, for example, a signal that reaches the H level after elapse of a certain time after operation of a switch for providing an instruction of start of operation of the railway vehicle and that reaches the L level at the end of the running of the railway vehicle.

Each of the multiple switching elements included in the power conversion circuit 62 is under on-off control with the corresponding gate signal output by the power conversion control circuit 61 and performs the switching operation. The operating voltage output by the constant-voltage power supply 36 allows each of the switching elements of the power conversion circuit 62 to perform the switching operation.

Through the switching operation of each of the switching elements, the power conversion circuit 62 converts the power supplied from the power collection device 31 into power to be supplied to the load device 37 and supplies the resultant power to the load device 37.

Similarly to the load device 33, the load devices 35 and 37 are each electronic equipment that consumes electric power, such as lightning equipment, an air conditioner, or an electric motor that is mounted in the railway vehicle.

Each of the constant-voltage power supplies 32, 34 and 36 outputs the operating voltage to the corresponding one of the power conversion devices 20, 40 and 60. Each of the constant-voltage power supplies 34 and 36 has configuration similar to that of the constant-voltage power supply 32. The constant-voltage power supply 34 starts operation upon startup of the power conversion device 40. In detail, the constant-voltage power supply 34 starts operation upon the startup command S2 directed to the power conversion device 40 reaching the H level, and outputs, to the power conversion circuit 42 included in the power conversion device 40, the operating voltage that is an alternating-current voltage for the switching operation of the switching elements.

The constant-voltage power supply 36 starts operation upon startup of the power conversion device 60. In detail, the constant-voltage power supply 36 starts operation upon the startup command S3 directed to the power conversion device 60 reaching the H level, and outputs, to the power conversion circuit 62 included in the power conversion device 60, the operating voltage that is an alternating-current voltage for the switching operation of the switching elements.

The degradation determination device 3 determines presence or absence of degradation in the constant-voltage power supplies 32, 34 and 36 from the startup times of the constant-voltage power supplies 32, 34 and 36. The degradation determination device 3 includes a signal processor 14 that generates, from output voltages V1, V2 and V3 of the constant-voltage power supplies 32, 34 and 36, the voltage data based on the amplitudes of the output voltages V1, V2 and V3. The degradation determination device 3 further includes a degradation determiner 15 that acquires the startup times of the constant-voltage power supplies 32, 34 and 36 from the startup commands S1, S2 and S3 and the voltage data of the constant-voltage power supplies 32, 34 and 36, and determines presence or absence of degradation in the constant-voltage power supplies 32, 34 and 36. The degradation determination device 3 has hardware configuration similar to that of the degradation determination device 1 according to Embodiment 1.

The signal processor 14 performs LPF-based filtering of waveform data indicating the output voltages V1, V2 and V3 of the constant-voltage power supplies 32, 34 and 36 and performs A/D conversion and thereby generates voltage data indicating the envelope of the waveform data of the output voltages of the constant-voltage power supplies 32, 34 and 36. The signal processor 14 transmits the generated voltage data of the constant-voltage power supplies 32, 34 and 36 to the degradation determiner 15.

The degradation determiner 15 acquires the startup commands S1, S2 and S3 directed to the power conversion devices 20, 40 and 60 respectively and acquires the voltage data of the constant-voltage power supplies 32, 34 and 36 from the signal processor 14. The degradation determiner 15 acquires the startup times of the constant-voltage power supplies 32, 34 and 36 from the startup commands S1, S2 and S3 directed to the power conversion devices 20, 40 and 60 respectively and the voltage data of the constant-voltage power supplies 32, 34 and 36. The method for acquiring the startup times is similar to that of Embodiment 1.

The degradation determiner 15 determines presence or absence of degradation in the constant-voltage power supplies 32, 34 and 36 from a variance in the startup time. For example, the degradation determiner 15 determines a deviation of the startup time of each of the constant-voltage power supplies 32, 34 and 36, and determines whether the deviation is greater than or equal to a standard deviation. The standard deviation is determined based on a difference in the startup time between a constant-voltage power supply with degradation and a constant-voltage power supply without degradation. The startup time of the constant-voltage power supply with degradation can be obtained through an accelerated degradation test, simulation, or the like. In the case where the deviation is greater than or equal to the standard deviation, it can be deemed as degradation occurs.

The degradation determination processing executed by the degradation determination device 3 is similar to the degradation determination processing executed by the degradation determination device 1 according to Embodiment 1 that is illustrated in FIG. 3. The processing in steps S12-S16 illustrated in FIG. 3 is executed for each of the constant-voltage power supplies 32, 34 and 36. In step S17, the degradation determiner 15 determines presence or absence of degradation in the constant-voltage power supplies 32, 34 and 36 from a variance of the startup times, as described above.

As described above, the degradation determination device 3 according to Embodiment 3 can determine presence or absence of degradation in the constant-voltage power supplies 32, 34 and 36 based on a variance of the startup times of the constant-voltage power supplies 32, 34 and 36.

The present disclosure is not limited to the above-described embodiments. The above-described embodiments may be freely combined. For example, the degradation determiner 15 included in the degradation determination device 3 may determine, for each of the constant-voltage power supplies 32, 34 and 36, presence or absence of degradation, based on the corresponding startup time of the constant-voltage power supplies 32, 34 and 36, similarly to the configuration of Embodiment 1. As another example, the configuration may be employed in which the degradation determination device 3 further includes the sign determiner 13 included in the degradation determination device 2 according to Embodiment 2 and the sign determiner 13 determines, for each of the constant-voltage power supplies 32, 34 and 36, presence or absence of a sign of degradation, based on the corresponding startup time of the constant-voltage power supplies 32, 34 and 36.

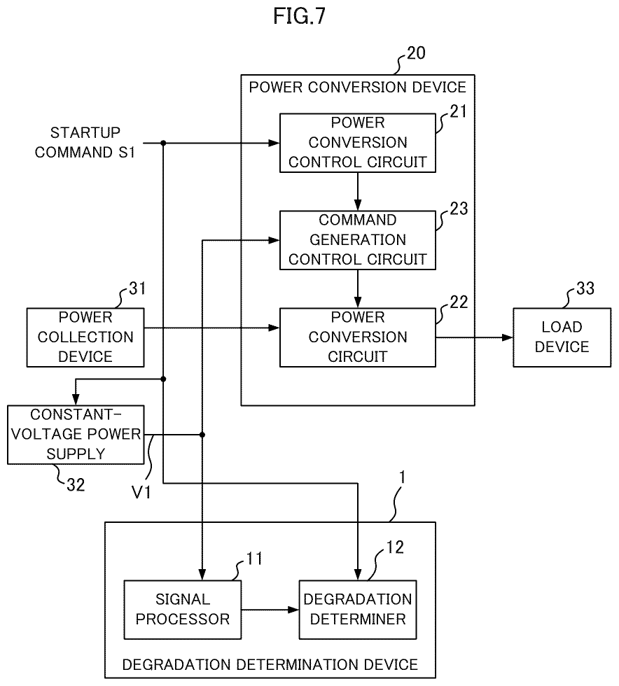

The above-described hardware configuration and flowchart are mere examples and may be freely changed and modified. As an example, the constant-voltage power supply 32 illustrated in FIG. 7 outputs the operating voltage to a command generation control circuit 23 included in the power conversion device 20. The gate signals are supplied from the power conversion control circuit 21 to the command generation control circuit 23, and the command generation control circuit 23 receives supply of the operating voltage from the constant-voltage power supply 32. The command generation control circuit 23 outputs the operating voltage to the power conversion circuit 22, based on the operating voltage supplied from the constant-voltage power supply 32. The command generation control circuit 23 transmits, based on the gate signals acquired from the power conversion control circuit 21, gate signals for control of the switching elements to the power conversion circuit 22.

The configuration and implementation manner of the degradation determination devices 1-3 are not limited to the above-described examples. For example, the degradation determination devices 1-3 may be implemented as one of the functions of a train information management system installed in the railway vehicle. As another example, the degradation determination devices 1-3 may be arranged as ground equipment, for example, at an operations control center. As still another example, the signal processors 11 and 14 included in the degradation determination devices 1-3 may be installed in the railway vehicle and the degradation determiners 12 and 15 and the sign determiner 13 that are included in the degradation determination devices 1-3 may be arranged as ground equipment.

In the case of the configuration in which the power conversion devices 20, 40 and 60 are started in response to a common startup command, the degradation determination device 3 may use, as a starting timing for counting the startup time of each of the constant-voltage power supplies 32, 34 and 36, a timing at which the common startup command reaches the H level.

The configuration of the power conversion circuits 22, 42 and 62 is not limited to the above-described example. For example, the power conversion circuits 22, 42 and 62 are not limited to an element that includes an inverter circuit, and may be an element that includes a converter circuit for converting alternating-current power supplied from the power collection device 31 into direct-current power and an inverter circuit for converting the direct-current power output by the converter circuit into an alternating-current power. As another example, the power conversion circuits 22, 42 and 62 may each be a direct-current-to-direct-current (DC-DC) converter. The number of the switching elements included in the power conversion circuits 22, 42 and 62 may be freely selected.

A portion that includes the processor 91, the memory 92, and the interface 93 and serves as a central part for executing control processing is not limited to a dedicated system and may be achieved by a general computer system. For example, the degradation determination devices 1-3 that execute the aforementioned processing may be achieved by storing a computer program for performing the above operations in a computer-readable recording medium (for example, a flexible disc, a compact disc-read only memory or CD-ROM, or a digital versatile disc-read only memory or DVD-ROM), distributing the computer program, and installing the computer program in a computer.

Furthermore, the degradation determination devices 1-3 may be achieved by storing the aforementioned computer program in a storage device included in a server device on a communication network and loading the computer program onto a general computer system.

In the case where the functions of the degradation determination devices 1-3 are achieved by allotment to an operating system (OS) and an application program or are achieved by cooperation between the OS and the application program, only a portion corresponding to the application program may be stored in a recording medium, a storage device, or the like.

The computer program may be distributed via a communication network by superimposing the computer program on a carrier wave. For example, the computer program may be posted on a bulletin board system (BBS) on the communication network to be distributed through the communication network. The above processing may be executed by launching the computer program and executing the program under the control of the OS in the same manner as other application programs.

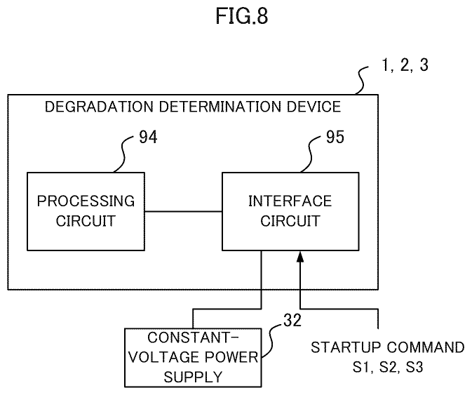

The degradation determination devices 1-3 may be achieved by a processing circuit 94, as illustrated in FIG. 8. The processing circuit 94 is connected to the constant-voltage power supply 32 and acquires the startup command S1 via an interface circuit 95. In the case where the processing circuit 94 is dedicated hardware, the processing circuit 94 is a single circuit, a combined circuit, a programmed processor, a parallel programmed processor, an application specific integrated circuit (ASIC), a field programmable gate array (FPGA), or a combination thereof, for example. Each element of the degradation determination device 1 may be achieved by an individual processing circuit 94 or by a common processing circuit 94.

Some of the functions of the degradation determination device 1 may be achieved by dedicated hardware, whereas other functions may be achieved by software or firmware. For example, the configuration may be employed in which the signal processor 11 is achieved by the processing circuit 94 illustrated in FIG. 8, whereas the degradation determiner 12 is achieved by a program stored in the memory 92 when the program is read and executed by the processor 91 illustrated in FIG. 2.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1, 2, 3 Degradation determination device
11, 14 Signal processor
12, 15 Degradation determiner
13 Sign determiner
20, 40, 60 Power conversion device
21, 41, 61 Power conversion control circuit
22, 42, 62 Power conversion circuit
23 Command generation control circuit
31 Power collection device
32, 34, 36 Constant-voltage power supply
33, 35, 37 Load device
90 Bus
91 Processor
92 Memory
93 Interface
94 Processing circuit
95 Interface circuit
S1, S2, S3 Startup command
V1, V2, V3 Output voltage

1. A degradation determination device for determining presence or absence of degradation in a constant-voltage power supply that outputs, to electronic equipment including a switching element, an operating voltage for switching operation of the switching element, the degradation determination device comprising:
signal processing circuitry to generate, from an output voltage of the constant-voltage power supply, voltage data based on an amplitude of the output voltage, by performing signal processing of the output voltage; and
degradation determining circuitry to acquire a startup time of the constant-voltage power supply from the voltage data and a startup command for providing an instruction for startup of the electronic equipment, and determine presence or absence of degradation in the constant-voltage power supply from the startup time.

2. The degradation determination device according to claim 1, wherein
the degradation determining circuitry acquires, as the startup time, an elapsed time from when the startup command instructs startup of the electronic equipment until the amplitude indicated by the voltage data reaches a threshold that is set based on an operating rated voltage necessary for the electronic equipment to perform the switching operation of the switching element.

3. The degradation determination device according to claim 1, wherein
the signal processing circuitry performs, based on a low pass filter, filtering of waveform data indicating the output voltage of the constant-voltage power supply that outputs to the electronic equipment the operating voltage that is an alternating-current voltage for the switching operation of the switching element and thereby generates envelope data in an analog domain indicating an envelope of the waveform data, and performs analog-to-digital conversion of the envelope data and thereby generates the voltage data in a digital domain.

4-6. (canceled)

7. The degradation determination device according to claim 2, wherein
the signal processing circuitry performs, based on a low pass filter, filtering of waveform data indicating the output voltage of the constant-voltage power supply that outputs to the electronic equipment the operating voltage that is an alternating-current voltage for the switching operation of the switching element and thereby generates envelope data in an analog domain indicating an envelope of the waveform data, and performs analog-to-digital conversion of the envelope data and thereby generates the voltage data in a digital domain.

8. A degradation determination device for determining presence or absence of degradation in a constant-voltage power supply that outputs, to electronic equipment including a switching element, an operating voltage for switching operation of the switching element, the degradation determination device comprising:
signal processing circuitry to perform, based on a low pass filter, filtering of waveform data indicating an output voltage of the constant-voltage power supply that outputs to the electronic equipment the operating voltage that is an alternating-current voltage for the switching operation of the switching element and thereby generate envelope data in an analog domain indicating an envelope of the waveform data, and perform analog-to-digital conversion of the envelope data and thereby generate voltage data based on an amplitude of the output voltage in a digital domain; and
degradation determining circuitry to acquire a startup time of the constant-voltage power supply from the voltage data and a startup command directed to the electronic equipment, and determine presence or absence of degradation in the constant-voltage power supply from the startup time.

9. The degradation determination device according to claim 1, wherein
the signal processing circuitry generates, from a plurality of the output voltages of a plurality of the constant-voltage power supplies that each output to a corresponding piece of the electronic equipment among a plurality of pieces of the electronic equipment installed in a same vehicle the operating voltage for the switching operation of the switching element included in the piece of the electronic equipment, for each of the plurality of constant-voltage power supplies, the voltage data based on the amplitude of the corresponding output voltage, and
the degradation determining circuitry acquires the startup time for each of the plurality of constant-voltage power supplies from the startup command directed to the corresponding piece of the electronic equipment and the voltage data of the constant-voltage power supply that outputs the operating voltage to the corresponding piece of the electronic equipment, and determines presence or absence of degradation from a variance in the startup time.

10. The degradation determination device according to claim 2, wherein
the signal processing circuitry generates, from a plurality of the output voltages of a plurality of the constant-voltage power supplies that each output to a corresponding piece of the electronic equipment among a plurality of pieces of the electronic equipment installed in a same vehicle the operating voltage for the switching operation of the switching element included in the piece of the electronic equipment, for each of the plurality of constant-voltage power supplies, the voltage data based on the amplitude of the corresponding output voltage, and
the degradation determining circuitry acquires the startup time for each of the plurality of constant-voltage power supplies from the startup command directed to the corresponding piece of the electronic equipment and the voltage data of the constant-voltage power supply that outputs the operating voltage to the corresponding piece of the electronic equipment, and determines presence or absence of degradation from a variance in the startup time.

11. The degradation determination device according to claim 3, wherein
the signal processing circuitry generates, from a plurality of the output voltages of a plurality of the constant-voltage power supplies that each output to a corresponding piece of the electronic equipment among a plurality of pieces of the electronic equipment installed in a same vehicle the operating voltage for the switching operation of the switching element included in the piece of the electronic equipment, for each of the plurality of constant-voltage power supplies, the voltage data based on the amplitude of the corresponding output voltage, and
the degradation determining circuitry acquires the startup time for each of the plurality of constant-voltage power supplies from the startup command directed to the corresponding piece of the electronic equipment and the voltage data of the constant-voltage power supply that outputs the operating voltage to the corresponding piece of the electronic equipment, and determines presence or absence of degradation from a variance in the startup time.

12. The degradation determination device according to claim 7, wherein
the signal processing circuitry generates, from a plurality of the output voltages of a plurality of the constant-voltage power supplies that each output to a corresponding piece of the electronic equipment among a plurality of pieces of the electronic equipment installed in a same vehicle the operating voltage for the switching operation of the switching element included in the piece of the electronic equipment, for each of the plurality of constant-voltage power supplies, the voltage data based on the amplitude of the corresponding output voltage, and
the degradation determining circuitry acquires the startup time for each of the plurality of constant-voltage power supplies from the startup command directed to the corresponding piece of the electronic equipment and the voltage data of the constant-voltage power supply that outputs the operating voltage to the corresponding piece of the electronic equipment, and determines presence or absence of degradation from a variance in the startup time.

13. The degradation determination device according to claim 8, wherein
the signal processing circuitry generates, from a plurality of the output voltages of a plurality of the constant-voltage power supplies that each output to a corresponding piece of the electronic equipment among a plurality of pieces of the electronic equipment installed in a same vehicle the operating voltage for the switching operation of the switching element included in the piece of the electronic equipment, for each of the plurality of constant-voltage power supplies, the voltage data based on the amplitude of the corresponding output voltage, and
the degradation determining circuitry acquires the startup time for each of the plurality of constant-voltage power supplies from the startup command directed to the corresponding piece of the electronic equipment and the voltage data of the constant-voltage power supply that outputs the operating voltage to the corresponding piece of the electronic equipment, and determines presence or absence of degradation from a variance in the startup time.

14. The degradation determination device according to claim 1, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

15. The degradation determination device according to claim 2, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

16. The degradation determination device according to claim 3, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

17. The degradation determination device according to claim 8, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

18. The degradation determination device according to claim 9, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

19. The degradation determination device according to claim 10, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

20. The degradation determination device according to claim 13, wherein
the degradation determining circuitry acquires the startup time each time the startup command instructs startup of the electronic equipment, and
the degradation determination device further includes sign determining circuitry that determines presence or absence of a sign of degradation in the constant-voltage power supply based on a change over time in the startup time acquired by the degradation determining circuitry.

21. A degradation determination method, comprising:
generating, from an output voltage of a constant-voltage power supply that outputs to electronic equipment including a switching element an operating voltage for switching operation of the switching element, voltage data indicating an amplitude of the output voltage, by performing signal processing of the output voltage; and
acquiring a startup time of the constant-voltage power supply from the voltage data and a startup command for providing an instruction for startup of the electronic equipment, and determining presence or absence of degradation in the constant-voltage power supply from the startup time.
